(19) United States
(12) Patent Application Publication
(10) Pub. No.: US 2016/0309598 A1
(43) Pub. Date: Oct. 20, 2016

(54) DISPLAY APPARATUS

(71) Applicant: JOLED INC., Tokyo (JP)

(72) Inventor: Kyohei YAMAGUCHI, Kanagawa (JP)

(73) Assignee: JOLED INC., Tokyo (JP)

(21) Appl. No.: 15/101,955

(22) PCT Filed: Dec. 4, 2014
(86) PCT No.: PCT/JP2014/006054

§ 371 Date: Jun. 6, 2016

(30) Foreign Application Priority Data
Dec. 10, 2013 (JP) 2013-255230

(51) Int. Cl. H05K 5/00; H01L 51/52; H05K 5/02

(52) U.S. Cl. CPC H05K 5/0017; H05K 5/0008; H05K 5/0217; H01L 51/5237

(57) ABSTRACT

A display apparatus includes: a plate-like chassis that is formed in a curved shape; a display panel that is curved along the curved shape of the chassis and attached to the chassis; and a holding member that abuts an end portion of the display panel and holds the display panel, and the holding member is slidably attached to the chassis.

### TECHNICAL FIELD

The present disclosure relates to a display apparatus.

### BACKGROUND ART

A display apparatus includes, for example, a thin-type display panel such as an organic EL (Electro Luminescent) display panel or a liquid crystal display panel. As a display apparatus of this type, a curved display including a curved display panel has been proposed (see, for example, Patent Literature (PTL) 1). In recent years, development has been made on, as a curved display for viewing television, a display apparatus having a structure in which a large screen display panel is curved.

A display panel can be curved by reducing the thickness of the panel by thinning a glass substrate thereof or by using a flexible substrate. That is, it is possible to obtain a curved display panel by curving a flat display panel by applying a bending stress. In this case, the display panel can maintain its curved state by being attached to, for example, a plate-like chassis that has been formed in a curved shape in advance (reinforcing member).

### CITATION LIST

### Patent Literature

[PTL 1] Japanese Unexamined Patent Application Publication No. 2003-280548

### SUMMARY OF INVENTION

### Technical Problem

When a display panel is attached to a chassis having a curved shape, it is not easy to curve the display panel so as to be held by the chassis.

For example, a structure can be conceived in which a curved display panel is clamped and held by holding members having an L-shaped cross section that are fixed to the end portions of two opposing sides of a plate-like chassis having a curved shape, but in this case, when the display panel is curved and attached to the chassis so as to conform to the curved shape of the chassis, the end portions of the display panel may collide (interfere) with the holding members.

The present disclosure has been made in view of the problem described above, and it is an object of the present disclosure to provide a display apparatus wherein a display panel can be easily attached to a chassis having a curved shape.

### Solution to Problem

In order to solve the above problem, one aspect of a display apparatus according to the present disclosure relates to a display apparatus including: a plate-like chassis that is formed in a curved shape; a display panel that is curved along the curved shape of the chassis and attached to the chassis; and a holding member that abuts an end portion of the display panel and holds the display panel, wherein the holding member is slidably attached to the chassis.

### Advantageous Effects of Invention

With the display apparatus according to the present disclosure, the holding member for holding the display panel is slidably attached to the chassis. With this configuration, when the display panel is curved and attached to the chassis having a curved shape, by sliding the holding member, a collision between the holding member and the display panel can be avoided. Accordingly, the display panel can be easily attached to the chassis having a curved shape.

### BRIEF DESCRIPTION OF DRAWINGS

FIG. 1 is an external perspective view of a display apparatus according to an embodiment.

FIG. 2 is an exploded perspective view showing a schematic configuration of a display panel and a chassis included in the display apparatus according to the embodiment.

FIG. 3 is a cross-sectional view illustrating an example of a method of assembling the display apparatus according to the embodiment.

FIG. 4 is a partially enlarged view illustrating the example of the method of assembling the display apparatus according to the embodiment (the enlarged view showing the vicinity of a first holding member).

FIG. 5 is a partially enlarged view illustrating the example of the method of assembling the display apparatus according to the embodiment (the enlarged view showing the vicinity of a second holding member).

### DESCRIPTION OF EMBODIMENTS

Hereinafter, embodiments according to the present disclosure will be described with reference to the drawings. Note that, however, each of the embodiments described below shows a specific preferable example of the present disclosure. Accordingly, the numerical values, shapes, materials, structural elements, the arrangement and connection of the structural elements, steps, the processing order of the steps, etc. shown in the following embodiments are mere examples, and therefore do not limit the scope of the claims. Thus, among the structural elements in the following embodiments, structural elements not recited in any one of the independent claims are described as arbitrary structural elements.

Note also that the diagrams are schematic diagrams, and thus are not necessarily drawn to scale. In addition, in the diagrams, the same reference numerals are given to substantially the same structural elements, and a redundant description is omitted or simplified.

### Embodiment

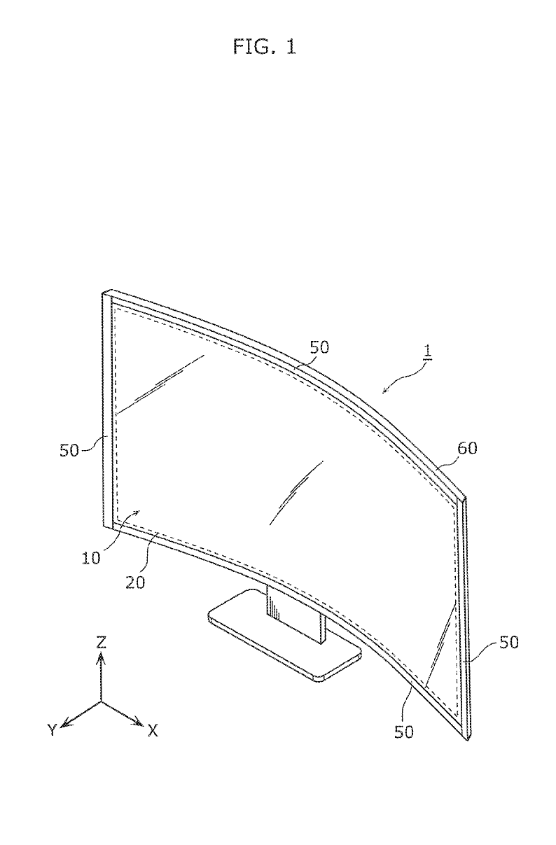

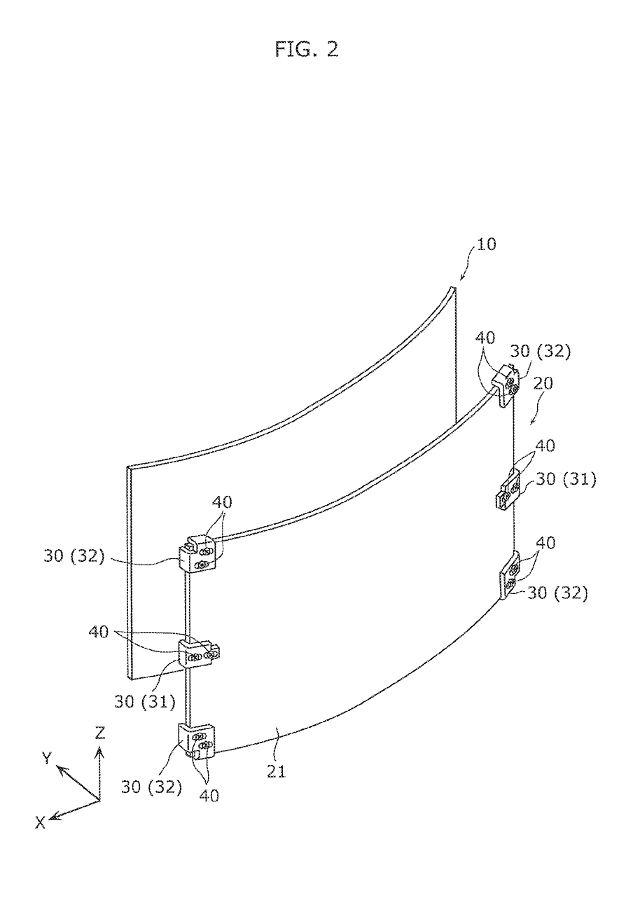

A schematic configuration of a display apparatus 1 according to an embodiment will be described first with reference to FIGS. 1 and 2. FIG. 1 is an external perspective view of the display apparatus 1 according to the embodiment. FIG. 2 is an exploded perspective view showing a schematic configuration of a display panel 10 and a chassis 20 included in the display apparatus 1 according to the embodiment. Note that the constituent members shown in FIG. 2 are drawn in a schematic manner.

As shown in FIGS. 1 and 2., the display apparatus 1 according to the present embodiment includes a display panel 10 for displaying an image, a chassis 20 to which the display panel 10 is attached, a holding member 30 (not shown in FIG. 1) that holds the display panel 10, and a screw 40 (not shown in FIG. 1) used to attach the holding member 30 to the chassis 20.

The display panel 10 is, for example, an organic EL display panel. Note that the display panel 10 is not limited to an organic EL display panel, and it may be other flat display panels such as an inorganic EL display panel, a liquid crystal display panel or a plasma display panel.

The display panel 10 is a rectangular panel having, for example, a vertical length of 500 to 800 mm and a horizontal length of 800 to 1400 mm. The display panel 10 has a thickness of, for example, about 1 to 3 mm.

As shown in FIG. 2, the display panel 10 is attached to the chassis 20 by being curved along the curved shape of the chassis 20. To be specific, by application of a bending stress onto the display panel 10, the display panel 10 is curved so as to conform to the curved shape of the chassis 20. The display panel 10 is thereby attached to the front surface (concave surface) of the chassis 20 while the display panel 10 is in a curved state.

In the present embodiment, the display panel 10 is configured so as to be curved only uniaxially, and for example, to be curved in a lengthwise direction of the display panel 10 when the display panel 10 is placed flat (before the display panel 10 is curved).

In the present embodiment, a display panel having a vertical length of 700 mm and a horizontal length of 1200 mm is used as the display panel 10, and the display panel 10 has a radius of curvature R of, for example, 1500 mm (R=1500 mm) when it is curved.

Also, in the display panel 10, one curved surface may have different radius of curvatures. For example, the radius of curvature of a center portion and the radius of curvature of left and right end portions may be different. In this case, it is preferable that the left and right end portions have a larger radius of curvature than that of the center portion, or may be flat. For example, the radius of curvature R of the left and right end portions may be set to 10000 mm or more, and the radius of curvature R of the center portion may be set to 5000 mm or less (for example, 1500 mm).

A detailed configuration of the display panel 10 will be given later.

The chassis 20 is an attachment plate to which the display panel 10 is attached. In the present embodiment, the chassis 20 is a plate-like member formed in a curved shape, and is a reinforcing plate for maintaining the curved state of the display panel 10. The chassis 20 is a rigid body made of a metal obtained by, for example, processing a rectangular plate member (metal plate) made of an aluminum alloy, an iron alloy or the like so as to have a curved shape having a predetermined radius of curvature. As the chassis 20, for example, an aluminum plate having a thickness of about 1 mm can be used.

In the present embodiment, the chassis 20 is formed so as to be capable of being curved only uniaxially, and can be produced by, for example, processing a rectangular flat metal plate so as to be curved in its lengthwise direction.

In order to improve the mechanical strength of the chassis 20, the chassis 20 may be subjected to drawing processing so as to have a concave and convex structure. Also, although not shown in the diagrams, on the back surface of the chassis 20, a driver circuit substrate and a power supply circuit substrate are attached, the driver circuit substrate including a plurality of driver circuits connected to the display panel 10 via a flexible cable.

As shown in FIG. 2, the holding member 30 is attached to an end portion in a curved direction of the chassis 20. To be specific, the holding member 30 is attached to an end portion of a short side of the chassis 20. In the present embodiment, the curved direction of the chassis 20 (the display panel 10) refers to a direction extending along the lengthwise direction of the curved surface of the chassis 20 (the display panel 10).

As will be described later, the holding member 30 has a function of holding the display panel 10 by abutting the end portion of the display panel 10, and a function of positioning the display panel 10.

Also, the holding member 30 is slidably attached to the chassis 20. In the present embodiment, the holding member 30 is fixed to the chassis 20 by a screw (male screw) 40, which is an example of a fastening member, and the holding member 30 is made slidable by loosening the screw 40. To be specific, the holding member 30 is slid linearly along the curved direction. That is, the holding member 30 is configured so as to be movable linearly within a certain range, and a predetermined movable region is set in the holding member 30.

Accordingly, in the display apparatus 1 according to the present embodiment, by rotating the screw 40 in a direction in which the screw 40 is fastened, the holding member 30 is made non-movable with respect to the chassis 20 and fixed to the chassis 20. At this time, the holding member 30 is fixed by being sandwiched between the chassis 20 and the screw head of the screw 40.

On the other hand, by rotating the screw 40 in a direction in which the screw 40 is loosened, the holding member 30 is made movable and thus can be moved along the surface of the chassis 20. That is, by loosening the screw 40, a gap is formed between the surface of the holding member 30 and the screw head of the screw 40, and the holding member 30 that has been damped by the screw 40 is released. The holding member 30 can be moved within an opening range of an insertion hole of the holding member 30 through which the screw 40 is inserted, which will be described later.

Note that even when the screw 40 is loosened, the screw 40 is not completely detached from the chassis 20, and thus the holding member 30 remains to be attached to the chassis 20 by the screw 40 even when the holding member 30 is made movable.

Also, the holding member 30 according to the present embodiment includes two first holding members 31, each attached to the center portion of each short side of the chassis 20, and four second holding members 32 respectively attached to four corners of the chassis 20. A detailed configuration of the first holding members 31 and the second holding members 32 will be described later.

Reverting to FIG. 1, the display apparatus 1 further includes: a bezel 50 that covers a perimeter along the display side surface of the display panel 10; and a back cover (back surface casing) 60 that covers the display panel 10 and the chassis 20.

The bezel 50 and the back cover 60 can be produced by, for example, unitary molding using a resin, or by subjecting a metal plate to press processing or the like, or by bonding a plurality of metal plates by welding.

The display apparatus 1 configured as described above is, for example, a television receiver that outputs an image signal and an audio signal obtained from received broadcast waves or the like.

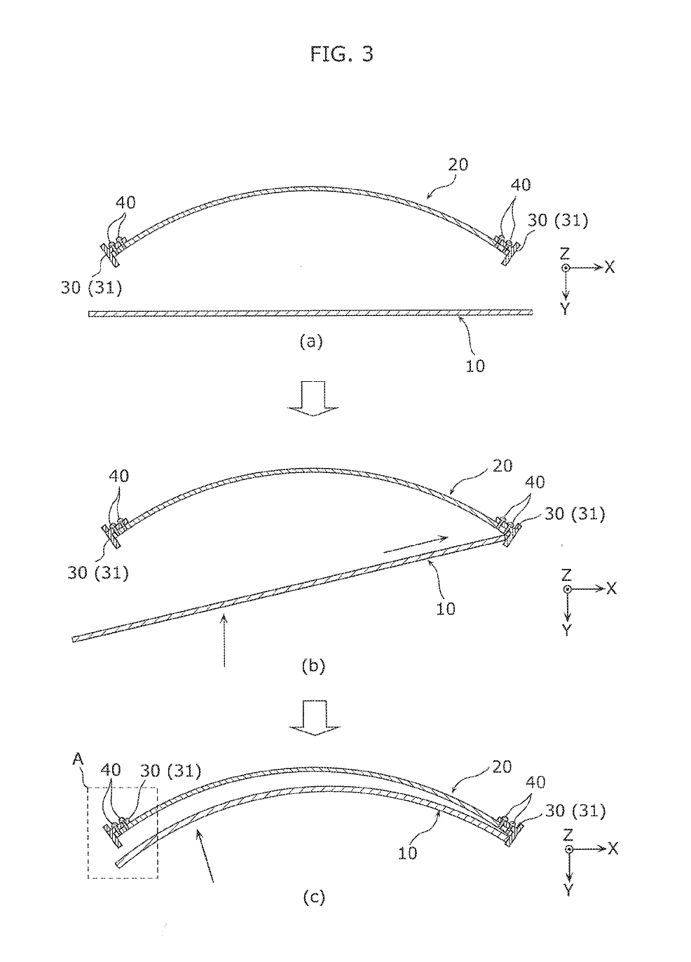

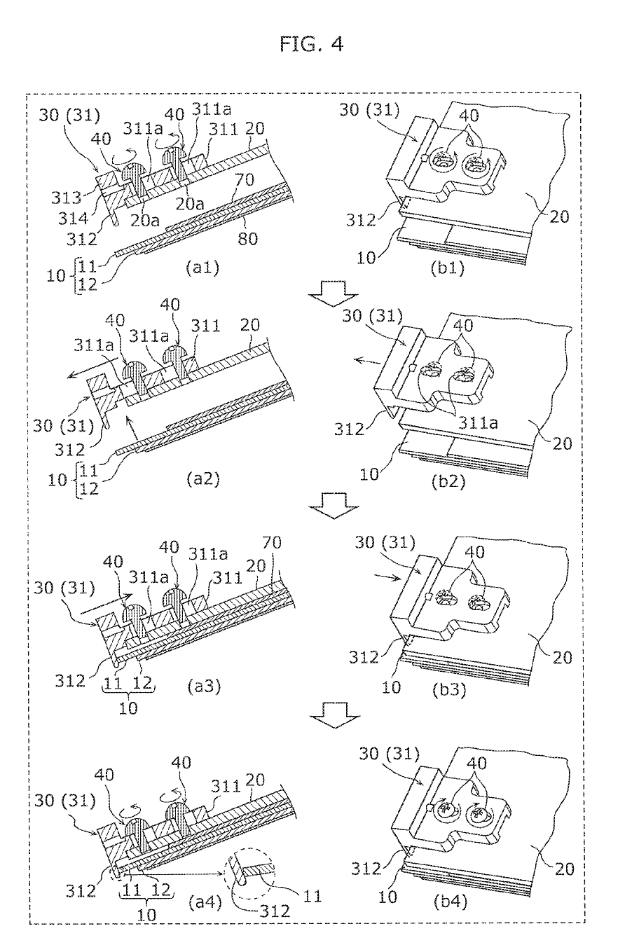

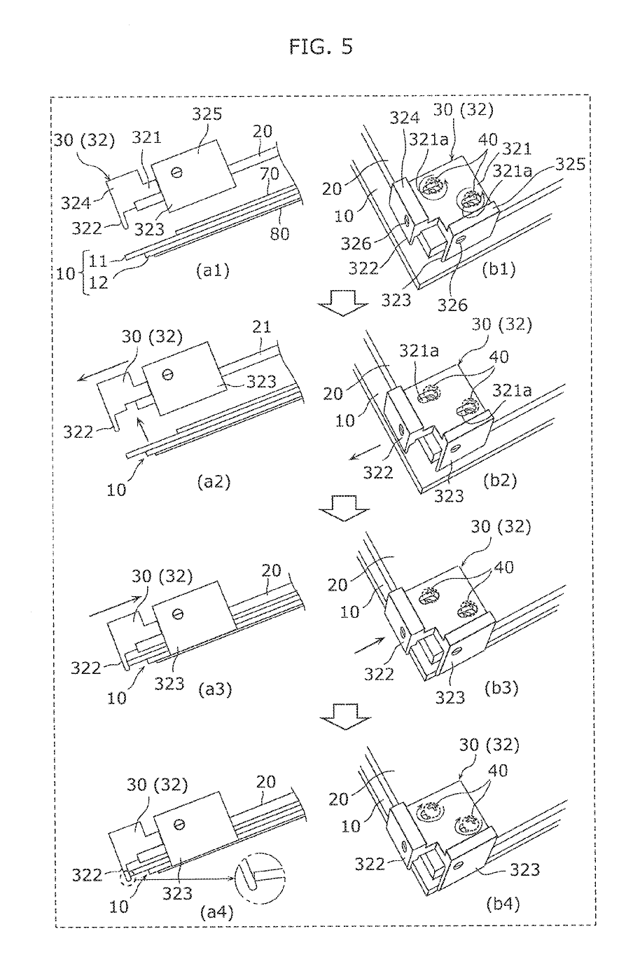

A method of assembling the display apparatus 1 according to the present embodiment will be described with reference to FIGS. 3 and 4. FIG. 3 is a cross-sectional view illustrating an example of a method of assembling the display apparatus 1 according to the present embodiment, and is a diagram showing a method of integrating the flat display panel 10 with the chassis 20 so as to conform to the chassis 20. FIG. 4 is a partially enlarged view illustrating the assembling method (the enlarged view showing the vicinity of a first holding member 31), and FIG. 5 is a partially enlarged view illustrating the assembling method (the enlarged view showing the vicinity of a second holding member 32).

As shown in (a) in FIG. 3, in the present embodiment, a rectangular flat display panel is used as the display panel 10, and a chassis that is formed in a curved shape in advance and to which the holding member 30 is attached is used as the chassis 20. Note that FIG. 3 shows only the first holding members 31, and the second holding members 32 are not shown.

When the display panel 10 is attached to the chassis 20, first, as shown in (b) in FIG. 3, one of the end portions in the lengthwise direction of the display panel 10 (the end portion on the right side in the diagram) is pressed against a corner constituted by one of the end portions in the lengthwise direction of the chassis 20 and a holding member 30 (first holding member 31). At this time, screws 40 are tightened, and a pair of right and left holding members 30 (first holding members 31) are fixed to the chassis 20.

Subsequently, as shown in (c) in FIG. 3, a bending stress is applied to the display panel 10 such that the shape of the display panel 10 follows the curved shape of the chassis 20. That is, the display panel 10 is pressed toward the inner surface of the chassis 20 such that the other end portion in the lengthwise direction of the display panel 10 (the end portion on the left side in the diagram) approaches the chassis 20. By doing so, the display panel 10 follows the inner surface shape of the chassis 20 and is curved and deformed.

If, at this time, the display panel 10 is pressed with a strong force in a short time, the display panel 10 may be broken. For this reason, it is preferable that the display panel 10 is gradually pressed so as to be slowly curved.

Next, the curved display panel 10 is caused to be held by the holding member 30, but if, at this time, the holding member 30 is fixed to the chassis 20 in a non-movable manner, the other end portion in the lengthwise direction of the display panel 10 (the end portion on the left side in the diagram) may collide (interfere) with the holding member 30, and the display panel 10 may he cracked or broken.

Particularly when, as described in connection to FIG. 3, a bending stress is applied to the fiat display panel 10 so as to allow the display panel 10 to follow the curved shape of the chassis 20, because the curved display panel 10 has a restoring force, the radius of curvature of the curved display panel 10 and the radius of curvature of the chassis 20 having a curved shape do not match. To be specific, the radius of curvature of the curved display panel 10 becomes larger than that of the chassis 20. As a result, a collision is likely to occur between the display panel 10 and the holding member 30.

If, on the other hand, in order to avoid the collision between the display panel 10 and the holding member 30, the holding member 30 is significantly offset outwardly with respect to the chassis 20 in advance and fixed to the chassis 20, a gap is formed between the display panel 10 and the holding member 30 when the display panel 10 is pressed toward the chassis 20. As a result, the holding member 30 does not abut the display panel 10, and thus the display panel 10 cannot be held by the holding member 30.

To address this, in the display apparatus 1 according to the present embodiment, the holding member 30 is slidably attached to the chassis 20. That is, the holding member 30 is allowed to have a movable region with respect to the chassis 20.

A method of assembling the display apparatus 1 according to the present embodiment and a detailed configuration and advantageous effects of the holding member 30 (a first holding member 31 and a second holding member 32) will be described in detail below with reference to FIGS. 4 and 5. Also, detailed configurations of the display panel 10 and the chassis 20 will also be described. FIG. 4 is an enlarged view of a region A surrounded by broken line in FIG. 3. Also, in FIGS. 4 and 5, screws 40 are partially illustrated in broken line.

First, detailed configurations of the display panel 10, the chassis 20 and the holding member 30 will be described.

As shown in (a1) and (b1) in FIG the display panel 10 includes two facing glass substrates 11 and 12. In the case where the display panel 10 is an organic EL display panel, an organic EL layer (light-emitting layer), an electrode, a transistor, a signal line and the like are provided between the glass substrate 11 and the glass substrate 12.

The glass substrates 11 and 12 have a thickness of, for example, 0.5 mm. Also, the glass substrate (TFT substrate) 11 has an extraction electrode and the like formed therein, and thus the glass substrate 11 is larger than the glass substrate (sealing substrate) 12.

A heat-dissipation sheet 70 such as an aluminum sheet is attached to the outer surface of the glass substrate 11. When the display panel 10 is attached to the chassis 20, the heat-dissipation sheet 70 is in contact with the inner surface of the chassis 20. Accordingly, heat generated from the display panel 10 can be efficiently transferred to the chassis 20. Also, an anti-reflection film (AR film) 80 is attached to the outer surface of the glass substrate 12.

In the chassis 20, screw holes 20a are formed at positions at which the first holding members 31 and the second holding members 32 are to be attached. Each of the screw holes 20a is a hole into which the shaft of a screw 40 that has passed through the first holding member 31 or the second holding member 32 is screwed. To be specific, the inner surface of the screw hole 20a is threaded (female thread).

In the present embodiment, the screw holes 20a are formed as through holes passing through the chassis 20, but may be recessed screw holes that do not pass through the chassis 20. That is, the screw holes 20a are screw holes. Also, in the present embodiment, in the chassis 20, a plurality of screw holes 20a are formed for each of the first holding members 31 and the second holding members 32.

Each of the first holding members 31 is configured so as to, when the display panel 10 is attached to the chassis 20, abut only the end portion of a short side of the display panel 10. To be specific, as shown in (a1) and (b1) in FIG. 4, the first holding member 31 includes a plate-like attachment portion 311 that is attached to the chassis 20 and an abutting portion 312 that abuts the end portion of the short side of the display panel 10 when holding the display panel 10.

The attachment portion 311 is in a surface contact with a surface of the chassis 20 that is opposite to the surface thereof to which the display panel 10 is attached. Also, the abutting portion 312 is in the form of a plate, and extends upright from the attachment portion 311 so as to protrude beyond the chassis 20. In the present embodiment, the attachment portion 311 and the abutting portion 312 are connected substantially at a right angle, and thus the first holding member 31 has a substantially L-shaped cross section. As described above, the first holding member 31 holds the display panel 10 by using the claw structure of the abutting portion 312.

The attachment portion 311 has an insertion hole (through hole) 311a through which the shaft of a screw 40 is inserted. The insertion hole 311a is formed at a position corresponding to each screw hole 20a of the chassis 20. In the present embodiment, the attachment portion 311 has a plurality of insertion holes 311a, and each of the plurality of insertion holes 311a is formed at an overlapping position that overlaps with the corresponding one of a plurality of screw holes 20a formed in the chassis 20 as viewed in plan view. The insertion holes 311a and the screw holes 20a are in one to one correspondence with each other.

Also, in order to make the first holding member 31 slidable, the size of the opening of each insertion hole 311a is larger than the diameter of the shaft of each screw 40. That is, the insertion hole 311a and the shaft of the screw 40 are configured to form a loose fit, and the range within which the shaft of the screw 40 can move in the opening of the insertion hole 311a is a movable region of the first holding member 31. In this way, in the present embodiment, the movable region of the first holding member 31 is set by the opening region of the insertion hole 311a.

In the present embodiment, the insertion hole 311a is an elongated hole having a length in the curved direction of the display panel 10 and the chassis 20 that is relatively longer than that in the other direction. That is, the insertion hole 311a is formed so as to be elongated in the sliding direction of the first holding member 31. The opening of the insertion hole 311a is in the form of, for example, a racetrack.

Also, the attachment portion 311 is provided with a protruding portion 313 having a height greater than the height of the head of the screw 40. The protruding portion 313 has an upper surface that is a flat surface. In other words, the thickness of the attachment portion 311 is reduced so as to form a recess in the vicinity of the region where the head of the screw 40 is present. With this configuration, the protruding portion 313 has a height greater than that of the head of the screw 40, and it is therefore possible to prevent the head of the screw 40 from sticking out.

The first holding ember 31 has a bezel hole 314 for screwing the bezel 50.

Meanwhile, each of the second holding members 32 is configured so as to, when the display panel 10 is attached to the chassis 20, abut not only the end portion of a short side of the display panel 10 but also the end portion of a long side of the display panel 10. To be specific, as shown in (a1) and (b1) in FIG. 5, the second holding member 32 has a plate-like attachment portion 321 that is attached to the chassis 20, a first abutting portion 322 that abuts the end portion of the short side of the display panel 10 when holding the display panel 10, and a second abutting portion 323 that abuts the end portion of the long side of the display panel 10.

The attachment portion 321 is in a surface contact with a surface of the chassis 20 that is opposite to the surface thereof to which the display panel 10 is attached. Also, the first abutting portion 322 and the second abutting portion 323 each are in the form of a plate, and extend upright from the attachment portion 321 so as to protrude beyond the chassis 20. In the present embodiment, the attachment portion 321 is connected to the first abutting portion 322 and the second abutting portion 323 so as to substantially form a right angle. Also, the first abutting portion 322 and the second abutting portion 323 are provided such that their main surfaces are substantially perpendicular to each other. The second holding member 32 holds the display panel 10 by using the claw structures of the first abutting portion 322 and the second abutting portion 323.

The attachment portion 321 has an insertion hole (through hole) 321a through which the shaft of a screw 40 is inserted. In the present embodiment, the attachment portion 321 has a plurality of insertion holes 321a, and each of the plurality of insertion holes 321a is formed at an overlapping position that overlaps with the corresponding one of a plurality of screw holes 20a of the chassis 20 as viewed in plan view.

Also, in order to make the second holding member 32 slidable, the size of the opening of each insertion hole 321a is larger than the diameter of the shaft of the screw 40. That is, the insertion hole 321a and the shaft of the screw 40 are configured to form a loose fit, and the range within which the shaft of the screw 40 can move in the opening of the insertion hole 321a is a movable region of the second holding member 32. In this way, in the second holding member 32 as well, the movable region of the second holding member 32 is set by the opening region of the insertion hole 321a.

In the present embodiment, the insertion hole 321a is an elongated hole having a length in the curved direction of the display panel 10 and the chassis 20 that is relatively longer than that in the other direction. That is, the insertion hole 321a is formed so as to be elongated in the sliding direction of the second holding member 32. As with the insertion hole 311a, the opening of the insertion hole 321a is in the form of a racetrack.

Also, as with the first holding member 31, the attachment portion 321 is provided with a first protruding portion 324 and a second protruding portion 325 having a height greater than the height of the head of the screw 40. With this configuration, it is possible to prevent the head of the screw 40 from sticking out. The first protruding portion 324 and the second protruding portion 325 have an upper surface that is a flat surface.

The second holding member 32 includes bezel holes 326 for screwing the bezel 50.

Each of the first holding members 31 and the second holding members 32 configured as described above is attached to the chassis 20 by using two screws 40.

In this case, the first holding member 31 is placed on the chassis 20 such that the insertion holes 311a and the screw holes 20a correspond to each other, and then the shaft of a screw 40 is inserted into each insertion hole 311a and screwed into the screw hole 20a. Likewise, the second holding member 32 is placed on the chassis 20 such that the insertion holes 321a and the screw holes 20a correspond to each other, and then the shaft of a screw 40 is inserted into each insertion hole 321a and screwed into the screw hole 20a.

A method of attaching the display panel 10 to the chassis 20 performed in the method of assembling the display apparatus 1 according to the present embodiment will be described next. Note that the first holding members 31 will be described with reference to FIG. 4, and the second holding members 32 will be described with reference to FIG. 5.

As shown in (a) to (c) in FIG. 3 described above, a bending stress is applied to the display panel 10 so as to curve the display panel 10 such that the shape of the display panel 10 follows the curved shape of the chassis 20, and thereafter the pressing of the display panel 10 is temporarily stopped, and as shown in (a1) and (a2) in FIG. 4, two screws 40 in the first holding member 31 are loosened. A gap is thereby formed between the heads of the screws 40 and the attachment portion 311 of the first holding member 31, and thus the first holding members 31 is made movable.

Likewise, in the second holding member 32, as shown in (a1) and (a2) in FIG. 5, by loosening two screws 40, the second holding member 32 is made movable.

The first holding member 31 and the second holding members 32 are attached to each of both end portions in the curved direction of the chassis 20, but it is sufficient to loosen only the screws 40 in the first holding member 31 and the second holding members 32 attached to one of the end portions of the chassis 20. Accordingly, the screws 40 in the first holding member 31 and the second holding members 32 attached to the other end portion of the chassis 20 remain to be fixed to the chassis 20 without being loosened.

Next, as shown in (a2) and (b2) in FIG. 4, the first holding member 31 is slid outwardly with respect to the chassis 20 along the curved direction, and as shown in (a2) and (b2) in FIG. 5, the second holding member 32 is slid outwardly with respect to the chassis 20 along the curved direction.

At this time, the first holding member 31 is slid until the abutting portion 312 of the first holding member 31 is positioned on the outside of the end portion of the display panel 10. Likewise, the second holding member 32 is slid until the first abutting portion 322 is positioned on the outside of the end portion of the display panel 10. In the present embodiment, sliding is performed until the shaft of each screw 40 abuts the inner surface of the insertion hole 311a (321a).

After that, the display panel 10 is pressed toward the chassis 20 until the end portion of the display panel 10 makes its closest approach to the chassis 20. By doing so, the entire display panel 10 is curved in a shape conforming to the inner surface shape of the chassis 20.

Next, as shown in (a3) and (b3) in FIG. 4, the first holding member 31 is slid inwardly of the chassis 20 along the curved direction, and as shown in (a3) and (b3) in FIG. 5, the second holding member 32 is slid inwardly of the chassis 20 along the curved direction.

At this time, the first holding member 31 is slid until the abutting portion 312 abuts the end portion (the end portion of the short side) of the display panel 10. Likewise, the second holding member 32 is slid until the first abutting portion 322 abuts the end portion (the end portion of the short side) of the display panel 10. By doing so, it is possible to eliminate the gap between the first holding member 31 and the display panel 10 and the cap between the second holding member 32 and the display panel 10 formed as a result of the first holding member 31 and the second holding member 32 being slid outwardly. At the time when the second holding member 32 is caused to abut the end portion of the display panel, the second abutting portion 323 is caused to abut the end portion of the long side of the display panel 10.

Next, as shown in (a4) and (b4) in FIG. 4, the screws 40 are tightened so as to fix the first holding member 31 to the chassis 20, and as shown in (a4) and (b4) in FIG. 5, the screws 40 are tightened so as to fix the second holding member 32 to the chassis 20.

By doing so, the display panel 10 is pressed against the chassis 20 while the display panel 10 is in a curved state, and sandwiched by one pair of opposing first holding members 31 and two pairs of opposing second holding members 32. In this way, the display panel 10 is positioned by the first holding members 31 and the second holding members 32 and held by the first holding members 31 and the second holding members 32.

At this time, the chassis 20 and the display panel 10 are curved, and thus the abutting portion 312 of each first holding member 31 and the first abutting portion 322 of each second holding member 32 abut the end portion of the display panel 10 so as to be positioned diagonally below the end portion of the display panel 10. That is, the abutting portion 312 of the first holding member 31 and the first abutting portion 322 of the second holding member 32 are positioned immediately vertically below the end portion of the display panel 10. With this configuration, the end portion of the display panel 10 is supported by the abutting portion 312 of the first holding member 31 and the first abutting portion 322 of the second holding member 32.

Accordingly, the display panel 10 can be held without providing an adhesive or a pressure-sensitive adhesive sheet between the display panel 10 and the chassis 20. In the present embodiment, the end portion of the display panel 10 is also supported by the second abutting portions 323 of the second holding members 32.

As described above, with the display apparatus 1 according to the present embodiment, the holding member 30 for holding the display panel 10 is slidably attached to the chassis 20.

With this configuration, when the display panel 10 is curved and attached to the chassis 20 having a curved shape, the holding member 30 can be slid, and thus a collision between the holding member 30 and the display panel 10 can be avoided. Accordingly, the display panel 10 can be easily attached to the chassis 20 having a curved shape.

Furthermore, because the holding member 30 is slidably attached to the chassis 20, it is also possible to detach the display panel 10 from the chassis 20 with ease. For example, at the time of replacement of the display panel 10, the display panel 10 can be detached from the chassis 20 with ease by sliding the holding member 30 so as to release the display panel 10 from its held state.

Also, in the present embodiment, the holding member 30 and the chassis 20 are fixed by the screw 40, which is a fastening member, and the holding member 30 is configured to be made slidable by loosening the screw 40.

Accordingly, it is possible to move or fix the holding member 30 with respect to the chassis 20 with a simple configuration. Also, in the present embodiment, in the first holding member 31, the abutting portion 312 that abuts the end portion of the curved display panel 10 extends upright from the attachment portion 311 that is in contact with a surface of the chassis 20 that is opposite to the surface thereof to which the display panel 10 is attached. Likewise, in the second holding member 32, the first abutting portion 322 that abuts the end portion of the curved display panel 10 extends upright from the attachment portion 321.

With this configuration, the end portion of the display panel 10 is supported by the abutting portion 312 of the first holding member 31 and the first abutting portion 322 of the second holding member 32, and thus the display panel 10 can be held without providing an adhesive or a pressure-sensitive adhesive sheet between the display panel 10 and the chassis 20. Accordingly, the display panel 10 can be attached to the chassis 20 with ease, and heat from the display panel 10 can be efficiently transferred to the chassis 20. Also, a reduction in the cost can be achieved.

Also, in the present embodiment, the attachment portion 311 of each first holding member 31 and the attachment portion 321 of each second holding member 32 have insertion holes 311a and 321a through which the shaft of a screw 40 is inserted, and the chassis 20 has screw holes 20a through which the shaft of a screw 40 is inserted.

Accordingly, it is possible to fix the first holding member 31 and the second holding member 32 to the chassis 20 by screwing the screws 40 into the chassis 20. Accordingly, the movable state and the nonmovable state of the holding member 30 can be switched with a simple configuration.

Also, in the present embodiment, each of the first holding members 31 and the second holding members 32 is attached to the chassis 20 by using a plurality of screws 40. To be specific, two screws 40 are used for one first holding member 31, and two screws 40 are used for one second holding member 32. Also, the attachment portions 311 and 321 has a plurality of insertion holes 311a and 321a corresponding to the number of screws 40, and the chassis 20 has a plurality of screw holes 20a.

As described above, by attaching each holding member 30 (first holding member 31, second holding member 32) to the chassis 20 by using a plurality of screws 40, it is possible to prevent the holding member 30 from rotating. That is, when the screws 40 are loosened, if there is only one screw 40, the holding member 30 may move in a direction of rotation about the screw 40, but by using a plurality of screws 40, the movement of the holding member 30 in the direction of rotation can be restricted.

Also, in the present embodiment, the insertion holes 311a and 321a formed in the holding member 30 (first holding member 31, second holding member 32) are elongated holes having a length in the sliding direction of the holding member 30 that is relatively longer than that in the other direction.

With this configuration, the holding member 30 can be slid along the lengthwise direction of the elongated holes of the insertion holes 311a and 321a.

Also, in the present embodiment, the attachment portions 311 and 321 of the holding member 30 (first holding member 31, second holding member 32) are provided with the protruding portion 313, the first protruding portion 324 and the second protruding portion 325 that have a height greater than the height of the head of the screw 40.

With this configuration, the head of the screw 40 can be prevented from sticking out, and thus a situation can be avoided in which a member such as the back cover 60 comes into contact with the screw 40. Accordingly, it is possible to prevent the screw 40 from unintentionally loosening as well as preventing a member such as the back cover 60 from being broken.

### (Variations, etc.)

One aspect of the display apparatus has been described above based on the embodiment, but the present disclosure is not limited to the embodiment given above.

It is possible to use, for example, a method in which the chassis 20 having a curved shape is integrated with the flat display panel 10 so as to conform to the flat display panel 10.

Also, in the embodiment given above, thin glass substrates are used as the substrate of the display panel 10, but it is also possible to use, instead of glass substrates, flexible substrates made of a flexible resin or the like.

Also, in the embodiment given above, the holding member 30 (first holding member 31, second holding member 32) is attached to the chassis 20 by using the screw 40, but the present disclosure is not limited thereto. Other fastening members such as bolts and nuts may be used as long as, for example, they can be tightened and loosened. Furthermore, the holding member 30 may be attached to the chassis 20 by using a member other than the fastening member as long as the movable state and the non-movable state of the holding member 30 can be switched.

Also, in the embodiment given above, the openings of the insertion holes 311a and 321a are in the form of a racetrack, but the present disclosure is not limited thereto. The openings of the insertion holes 311a and 321a may have, for example, an oval shape, an elliptic shape, a rectangular shape, or the like.

Also, in the embodiment given above, the protruding portions 313 and 324 are provided in order to prevent the heads of the screws 40 from sticking out, but instead of the protruding portions 313 and 324, a recess portion (countersink portion) for housing the head of a screw 40 may be formed in the attachment portions 311 and 321.

Also, in the embodiment given above, when the display panel 10 is attached to the chassis 20, among the first holding members 31 and the second holding members 32 of both end portions in the lengthwise direction of the chassis 20, only the first holding member 31 and the second holding members 32 of one of the end portions are slid, but the first holding members 31 and the second holding members 32 of both end portions may he slid.

Also, in the embodiment given above, it has been stated that the display apparatus is a television receiver, but the present disclosure is not limited thereto. The display apparatus may be a monitor display for displaying an externally input image, a digital signage device used as an advertisement medium, or a portable terminal, a tablet terminal or a table-type display apparatus that receives a user operation through a touch panel.

The present disclosure also encompasses other embodiments obtained by making various modifications conceived by a person skilled in the art to the embodiment and variations disclosed herein, as well as embodiments implemented by any combination of the structural elements and functions of the embodiment and variations disclosed herein without departing from the scope of the present disclosure.

### INDUSTRIAL APPLICABILITY

The present disclosure is useful in, for example, a display apparatus that is required to be thin, and is applicable to an electronic device such as a television receiver, a monitor display, a digital signage device, a portable terminal, a tablet terminal or a table-type display apparatus.

### REFERENCE SIGNS LIST

1 Display Apparatus

10 Display Panel

20 Chassis

20a Screw Hole

30 Holding Member

31 First Holding Member

32 Second Holding Member

40 Screw

50 Bezel

60 Back Cover

70 Heat-Dissipation Sheet

80 Anti-Reflection Film

311, 321 Attachment Portion

311a, 321a Insertion Hole

312 Abutting Portion

313 Protruding Portion

314, 326 Bezel Hole

322 First Abutting Portion

323 Second Abutting Portion

324 First Protruding Portion

325 Second Protruding Portion

1. A display apparatus comprising:
a plate-like chassis that is formed in a curved shape;
a display panel that is curved along the curved shape of the chassis and attached to the chassis; and
a holding member that abuts an end portion of the display panel and holds the display panel,
wherein the holding member is slidably attached to the chassis.

2. The display apparatus according to claim 1,
wherein the holding member and the chassis are fixed by a fastening member, and
the holding member is made slidable by loosening the fastening member.

3. The display apparatus according to claim 2,
wherein the holding member includes an attachment portion that is attached to the chassis and an abutting portion that abuts the end portion of the display panel,
the attachment portion is in contact with a surface of the chassis that is opposite to a surface of the chassis to which the display panel is attached, and
the abutting portion extends upright from the attachment portion.

4. The display apparatus according to claim 3,
wherein the fastening member is a screw,
the attachment portion has an insertion hole through which a shaft of the screw is inserted, and
the chassis has a screw hole through which the shaft of the screw that has passed through the holding member is inserted.

5. The display apparatus according to claim 4,
wherein the holding member is attached to the chassis by a plurality of the screws,
the attachment portion has a plurality of the insertion holes, and
the chassis has a plurality of the screw holes corresponding to the plurality of the insertion holes.

6. The display apparatus according to claim 4,
wherein the insertion hole is an elongated hole having a relatively long length in a sliding direction of the holding member.

7. The display apparatus according to claim 4,
wherein the attachment portion includes a protruding portion having a height greater than a height of a head of the screw.
